(19) United States
(12) Patent Application Publication
(10) Pub. No.: US 2024/0240021 A1
(43) Pub. Date: Jul. 18, 2024

(54) INFRARED-TRANSMISSIVE CURABLE COMPOSITION, CURED PRODUCT THEREFROM, AND OPTICAL SEMICONDUCTOR DEVICE

(71) Applicant: SHIN-ETSU CHEMICAL CO., LTD., Tokyo (JP)

(72) Inventor: Eri ASAKURA, Annaka-shi (JP)

(73) Assignee: SHIN-ETSU CHEMICAL CO., LTD., Tokyo (JP)

(21) Appl. No.: 17/773,128

(22) PCT Filed: Sep. 24, 2020
(86) PCT No.: PCT/JP2020/035997

§ 371 Date: Mar. 6, 2024

(30) Foreign Application Priority Data
Nov. 1, 2019 (JP) 2019-199486

(51) Int. Cl. C08L 83/16; C08K 3/36; H01L 33/44; H01L 33/56

(52) U.S. Cl. CPC C08L 83/16; C08K 3/36; H01L 33/44; H01L 33/56; C08L 2205/025

(57) ABSTRACT

A composition comprising components (A) to (E) below, due to an excellent compatibility with dyes, can inhibit timewise dye aggregation, and has a high infrared transmissivity and a high visible light-blocking performance.
(A) An addition reaction product between a compound (a) with formula (1) and a polycyclic hydrocarbon (b) having two carbon-carbon double bonds in each molecule, the addition reaction product having two carbon-carbon double bonds in each molecule

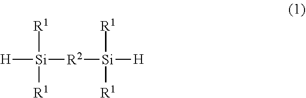

(R¹ represents, e.g., a monovalent hydrocarbon group, and R² represents a divalent hydrocarbon group)
(B) A dye that has an absorption band in the wavelength region of 350-650 nm and that transmits at least a portion of light having a wavelength of 800-900 nm
(C) An organosilicon compound having in each molecule at least two silicon atom-bonded hydrogen atoms, and lacking a carboxylic acid anhydride group, alkoxysilyl group, epoxy group, or a group containing an addition-reactive carbon-carbon double bond
(D) A hydrosilylation reaction catalyst
(E) Hydrophobic fumed silica.

### TECHNICAL FIELD

This invention relates to an infrared-transmissive curable composition, a cured product thereof, and an opto-semiconductor package.

### BACKGROUND ART

Recently, sensors are mounted on a variety of electronic equipment and instruments. Light-emitting diodes (LEDs) are used as the infrared radiation emitting/detecting device in the sensors.

Since these sensors malfunction by visible light, it is necessary to combine filters or coating agents with the light source so as to block visible light and transmit only infrared radiation.

While current LEDs are modified toward higher luminance and accordingly generate more heat, efforts are made to develop durable infrared-transmissive encapsulants based on silicone resins or curable resins having an organosilicon skeleton (see Patent Document 1). Since these resins are less compatible with dyes, a problem arises that the dyes are likely to agglomerate in resin compositions with the lapse of time.

The inventor already discovered a material which is fully compatible with dyes and effective for preventing dyes from agglomerating (see Patent Document 2). With this material, there is still left room for improvement in the prevention of dye agglomeration with time.

### PRIOR ART DOCUMENTS

### Patent Documents

Patent Document 1: JP-A 2010-121117
Patent Document 2: JP-A 2019-131806

### SUMMARY OF INVENTION

### Technical Problem

An object of the invention, which has been made under the above-mentioned circumstances, is to provide an infrared-transmissive curable composition which is fully compatible with dyes, prevents dyes from agglomerating with the lapse of time, and has high infrared transmittance and visible light blockage, a cured product of the composition, and an opto-semiconductor package using the composition.

### Solution to Problem

Making extensive investigations to solve the above problem, the inventor has found that a composition comprising the following components (A) to (E) is fully compatible with the dye so that the dye may not agglomerate together and cures into a product which is highly infrared transmissive and visible light blocking. The invention is predicated on this finding.

The invention provides the following.

1. An infrared-transmissive curable composition comprising components (A) to (E):
(A) an addition reaction product between (a) a compound having two silicon-bonded hydrogen atoms per molecule, represented by the formula (1) and (b) a polycyclic hydrocarbon having two addition-reactive carbon-carbon double bonds per molecule, the addition reaction product having two addition-reactive carbon-carbon double bonds per molecule,

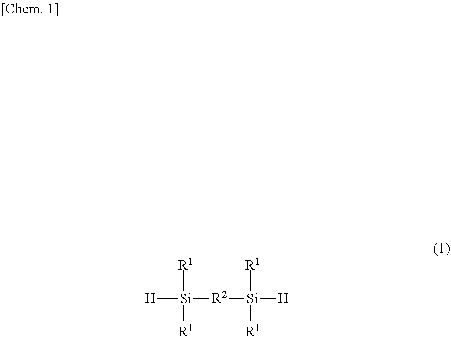

wherein R¹ is each independently a C₁-C₁₂ monovalent hydrocarbon group or C₁-C₆ alkoxy group, which may be substituted with halogen, cyano or glycidoxy, and R² is a C₁-C₁₂ substituted or unsubstituted divalent hydrocarbon group,
(B) a dye having an absorption band in the wavelength region of 350 to 650 nm and capable of transmitting at least a portion of light of wavelength 800 to 900 nm,
(C) an organosilicon compound having at least two silicon-bonded hydrogen atoms per molecule, and free of a group selected from an addition-reactive carbon-carbon double bond-containing group, epoxy group, alkoxysilyl group, amide group, and carboxylic anhydride group,
(D) a hydrosilylation reaction catalyst, and
(E) hydrophobic fumed silica.
   2. The infrared-transmissive curable composition of 1 wherein the polycyclic hydrocarbon is at least one of 5-vinylbicyclo[2.2.1]hept-2-ene and 6-vinylbicyclo[2.2.1]hept-2-ene.
   3. The infrared-transmissive curable composition of 1 or 2 wherein component (A) has the formula (2):

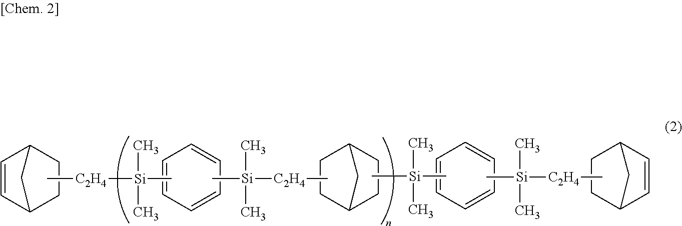

wherein n is an integer of 0 to 50.
4. A cured product of the infrared-transmissive curable composition of any one of 1 to 3, having an average light transmittance of up to 40% over wavelength 350 to 650 nm and an average light transmittance of at least 60% over wavelength 800 to 900 nm at both a thickness of 2 mm and 0.4 mm.
5. An opto-semiconductor package comprising an opto-semiconductor device encapsulated with a cured product of the infrared-transmissive curable composition of any one of 1 to 3.

### Advantageous Effects of Invention

The infrared-transmissive curable composition of the invention cures into a product having improved IR transmittance and visible light blockage.

The IR-transmissive curable composition prevents the dye from agglomerating with the lapse of time and is improved in storage stability, allowing for a choice of the type and addition amount of dye from a wide range.

Owing to such properties, the IR-transmissive curable composition is useful in the optical device application, especially as coating agents or adhesives for IR emitting/detecting devices and optical parts and encapsulants for opto-semiconductor devices.

### BRIEF DESCRIPTION OF DRAWINGS

FIG. 1 is a diagram showing the UV/Vis transmission spectrum of the cured product (film thickness 0.4 mm) prepared in Example 1.

FIG. 2 is a diagram showing the UV/Vis transmission spectrum of the cured product (film thickness 0.4 mm) prepared in Example 2.

FIG. 3 is a diagram showing the UV/Vis transmission spectrum of the cured product (film thickness 0.4 mm) prepared in Comparative Example 1.

FIG. 4 is a diagram showing the UV/Vis transmission spectrum of the cured product (film thickness 0.4 mm) prepared in Comparative Example 2.

### DESCRIPTION OF EMBODIMENTS

Now the invention is described in detail.

The invention provides an IR-transmissive curable composition comprising (A) an addition reaction product between (a) a compound having two silicon-bonded hydrogen atoms per molecule, represented by the formula (1) and (b) a polycyclic hydrocarbon having two addition-reactive carbon-carbon double bonds per molecule, the addition reaction product having two addition-reactive carbon-carbon double bonds per molecule, (B) a dye having an absorption band in the wavelength region of 350 to 650 nm and capable of transmitting at least a portion of light of wavelength 800 to 900 nm, (C) an organosilicon compound having at least two silicon-bonded hydrogen atoms per molecule, and free of an addition-reactive carbon-carbon double bond-containing group, epoxy group, alkoxysilyl group, amide group, and carboxylic anhydride group, (D) a hydrosilylation reaction catalyst, and (E) hydrophobic fumed silica.

As used herein, the term “addition-reactive” refers to susceptibility to addition reaction by hydrosilylation reaction with silicon-bonded hydrogen (sometimes referred to as “SiH,” hereinafter).

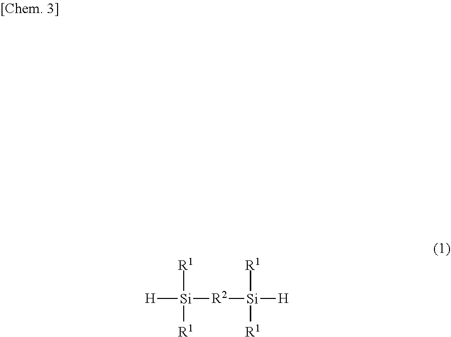

Herein R¹ is each independently a C₁-C₁₂ monovalent hydrocarbon group or C₁-C₆ alkoxy group, which may be substituted with halogen, cyano or glycidoxy, and R² is a C₁-C₁₂ substituted or unsubstituted divalent hydrocarbon group.

### [1] Component (A)

Component (A) is an addition reaction product between (a) a compound having two silicon-bonded hydrogen atoms per molecule, represented by the formula (1) and (b) a polycyclic hydrocarbon having two addition-reactive carbon-carbon double bonds per molecule, the addition reaction product having two addition-reactive carbon-carbon double bonds per molecule.

In the compound (a) having two silicon-bonded hydrogen atoms per molecule, represented by formula (1), examples of the C₁-C₁₂ monovalent hydrocarbon group R¹ include C₁-C₁₂ alkyl groups such as methyl, ethyl, n-propyl, isopropyl, n-butyl, isobutyl, sec-butyl, tert-butyl, n-pentyl, n-hexyl, n-octyl, n-decyl, cyclopentyl, and cyclohexyl; C₂-C₁₂ alkenyl groups such as vinyl, 1-propenyl, allyl (or 2-propenyl), hexenyl, octenyl, cyclopentenyl, and cyclohexenyl; C₆-C₁₂ aryl groups such as phenyl and naphthyl; C₇-C₁₂ alkylaryl groups such as tolyl, xylyl, ethylphenyl, propylphenyl, butylphenyl, pentylphenyl, and hexylphenyl; C₇-C₁₂ aralkyl groups such as benzyl and phenethyl.

Examples of the C₁-C₆ alkoxy group include methoxy, ethoxy, n-propoxy, i-propoxy, n-butoxy, sec-butoxy, t-butoxy, n-pentyloxy, n-hexyloxy, cyclopentyloxy, and cyclohexyloxy. Among these groups of R¹, C₁-C₁₂ monovalent hydrocarbon groups free of addition-reactive carbon-carbon double bond are preferred, and C₁-C₈ alkyl groups are more preferred, with methyl being most preferred.

Examples of the C₁-C₁₂ divalent hydrocarbon group R² include C₁-C₁₂ straight, branched or cyclic alkylene groups such as methylene, ethylene, propylene, trimethylene, pentamethylene, hexamethylene, heptamethylene, octamethylene, nonamethylene and decamethylene; C₆-C₁₂ arylene groups such as phenylene, biphenylene and naphthylene; and C₇-C₁₂ aralkylene groups such as phenylmethylene and methylenephenylenemethylene.

Among these groups, C₆-C₁₂ arylene groups are preferred, with phenylene being most preferred.

Examples of the compound having formula (1) include those of the following formulae, but are not limited thereto. Me stands for methyl (the same holds true, hereinafter).

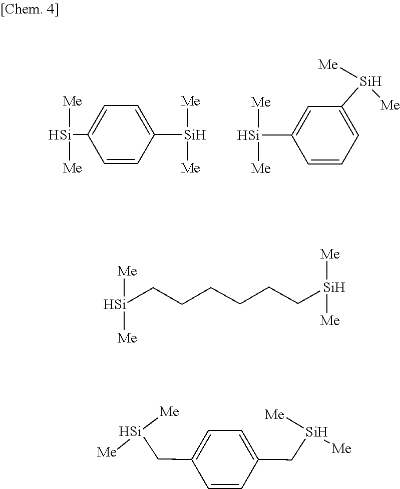

The compounds having formula (1) may be used alone or in admixture of two or more.

The polycyclic hydrocarbon (b) having two addition-reactive carbon-carbon double bonds per molecule, used herein, may be selected from (i) a polycyclic hydrocarbon wherein an addition-reactive carbon-carbon double bond is formed between two adjoining carbon atoms among carbon atoms of the hydrocarbon skeleton, (ii) a polycyclic hydrocarbon wherein a hydrogen atom attached to a carbon atom in the hydrocarbon skeleton is substituted by an addition-reactive carbon-carbon double bond-containing group, and (iii) a polycyclic hydrocarbon wherein an addition-reactive carbon-carbon double bond is formed between two adjoining carbon atoms among carbon atoms of the hydrocarbon skeleton and a hydrogen atom attached to a carbon atom in the hydrocarbon skeleton is substituted by an addition-reactive carbon-carbon double bond-containing group.

Examples of the polycyclic hydrocarbon include 5-vinylbicyclo[2.2.1]hept-2-ene having the formula (3) and 6-vinylbicyclo[2.2.1]hept-2-ene having the formula (4), shown below, which may also be used as a mixture. These three are collectively referred to as “vinylnorbornene” when it is unnecessary to distinguish them.

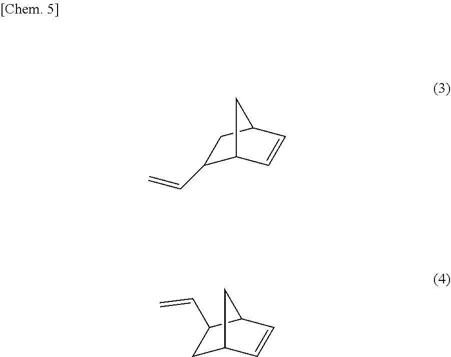

It is noted that the substitution position of vinyl group on the vinylnorbornene may be either cis-arrangement (exo form) or trans-arrangement (endo form). Since no significant difference in reactivity of the compound is acknowledged depending on whether the arrangement is cis or trans, a combination of isomers of both arrangements is acceptable.

The addition reaction product as component (A) can be synthesized, for example, by the method of JP-A 2005-133073.

In one example, it may be prepared by using the polycyclic hydrocarbon (b) in an amount of more than 1 mole to 10 moles, preferably more than 1 mole to 5 moles per mole of the compound (a) having formula (1) and effecting addition reaction in the presence of a hydrosilylation reaction catalyst.

The hydrosilylation reaction catalyst used herein may be any of well-known catalysts, for example, platinum-based catalysts such as platinum metal carried on carbon powder, platinum black, platinic chloride, chloroplatinic acid, reaction products of chloroplatinic acid with monohydric alcohols, complexes of chloroplatinic acid with olefins, and platinum bisacetoacetate, platinum group metal-based catalysts such as palladium-based catalysts and rhodium-based catalysts. Since no particular limits are imposed on the addition reaction conditions and the use of solvent, the reaction may be performed in the standard manner.

Since the addition reaction product as component (A) is synthesized by reacting the excessive molar amount of the polycyclic hydrocarbon (b) with the compound (a) having formula (1), the addition reaction product contains two addition-reactive carbon-carbon double bonds derived from the polycyclic hydrocarbon (b).

As component (A) or the addition reaction product, those having the following formula (5) are preferred, and especially those having the formula (5) wherein R¹ is methyl, that is, the following formula (2) are more preferred.

These addition reaction products containing polycyclic hydrocarbon and phenylene groups are highly compatible with dyes and cure into products having satisfactory hardness, crack resistance, and heat resistance. They may be advantageously used.

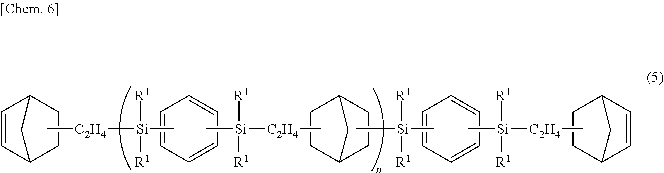

Herein R¹ is as defined above, preferably methyl, and n is an integer of 0 to 50, preferably 0 to 30, more preferably 0 to 20.

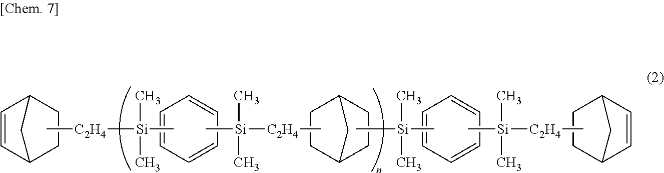

Herein n is as defined above.

### [2] Component (B)

Component (B) is a dye having an absorption band in the wavelength region of 350 to 650 nm and capable of transmitting at least a portion of light of wavelength 800 to 900 nm.

Suitable dyes include anthraquinone, perinone, and quinophthalone dyes, which are commercially available.

Commercially available dyes include elixa Black 850 (Orient Chemical Industries Co., Ltd.), SDO-12, SDO-2, Plast Black 8995, Plast Yellow 8005, Oil Green 5602, Plast Orange 8150, Plast Orange 8170, Plast Red 8370, and Plast Black DA423 (by Arimoto Chemical Co., Ltd.).

Component (B) or the dye may be used alone or in admixture of two or more. A pigment, inorganic material or the like may be used along with the dye insofar as the desired visible light blockage and IR transmittance are not negated.

The amount of component (B) or the dye used may be adjusted as appropriate depending on the thickness of the cured product, and is preferably 0.0001 to 20 parts by weight, more preferably 0.001 to 10 parts by weight, even more preferably 0.05 to 5.0 parts by weight per 100 parts by weight of component (A).

### [3] Component (C)

Component (C) is an organosilicon compound having at least two, preferably 2 to 300 silicon-bonded hydrogen atoms (i.e., SiH groups) per molecule, and free of a group selected from an addition-reactive carbon-carbon double bond-containing group, epoxy group, alkoxysilyl group, amide group, and carboxylic anhydride group.

SiH groups in the organosilicon compound undergo hydrosilylation reaction with addition-reactive carbon-carbon double bonds in component (A). When component (C) or organosilicon compound has a straight or branched structure, the SiH groups may be located at either one of an end of the molecular chain and a non-end position of the molecular chain or both.

The number of silicon atoms per molecule (i.e., degree of polymerization) of the organosilicon compound as component (C) is preferably 1 to 1,000, more preferably 1 to 200.

The organosilicon compound as component (C) is preferably liquid at 25° C., and has a viscosity at 25° C. of preferably 1 to 3,000 mPa·s, more preferably 5 to 2,000 mPa·s as measured by a rotational viscometer.

Examples of the organosilicon compound used as component (C) include compounds having the formula (6).

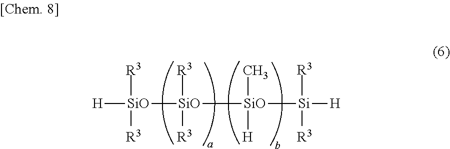

Herein R³ is each independently hydrogen, or a C₁-C₁₂ monovalent hydrocarbon group which may be substituted with halogen, “a” is an integer of 1 to 100, and “b” is an integer of 0 to 100. The arrangement of siloxane units within the parentheses with “a” and “b” may be random, alternate or blockwise.

Examples of the optionally halo-substituted C₁-C₁₂ monovalent hydrocarbon group R³ include C₁-C₁₂ alkyl or haloalkyl groups and C₆-C₁₂ aryl groups. Illustrative examples of the alkyl and aryl groups are as exemplified above for the group R¹. Of these, methyl or phenyl is preferred as R³.

Especially from the aspect of compatibility with the dye, it is preferred that at least 30 mol % of all the silicon-bonded substituent groups in component (C) be phenyl. Preferred examples of the compound having formula (6) are shown below, but not limited thereto. Ph stands for phenyl (the same holds true, hereinafter).

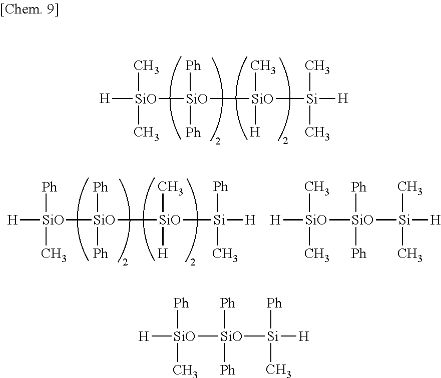

Organosilicon compounds having the following formulae (7) and (8) are also useful as component (C).

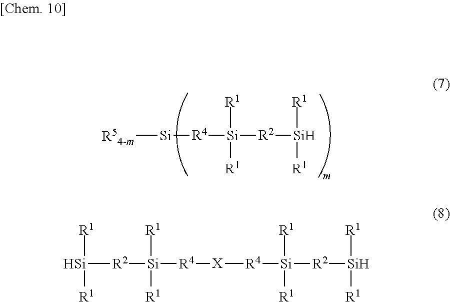

In formulae (7) and (8), R¹ and R² are as defined above, R⁴ is each independently a C₁-C₁₂ divalent hydrocarbon group, R⁵ is each independently a C₁-C₁₂ monovalent hydrocarbon group, X is a divalent linking group, and m is an integer of 2 or 3.

Examples of the divalent hydrocarbon group R⁴ are as exemplified above for the group R², preferably C₁-C₆ alkylene groups, more preferably ethylene and trimethylene.

Examples of the monovalent hydrocarbon group R⁵ are as exemplified above for the group R¹, preferably C₁-C₁₂ alkyl groups and C₆-C₁₂ aryl groups, more preferably methyl and phenyl.

Preferred examples of the divalent linking group X include C₁-C₁₂ divalent hydrocarbon groups in which a carbon-carbon bond in the chain may be replaced by an ether bond, ester bond, urethane bond or urea bond, and straight, branched or cyclic divalent siloxane chains. Examples of the divalent hydrocarbon group are as exemplified above for the group R², preferably C₁-C₁₂ alkylene groups.

Preferred examples of the organosilicon compounds having the formulae (7) and (8) are shown below, but not limited thereto.

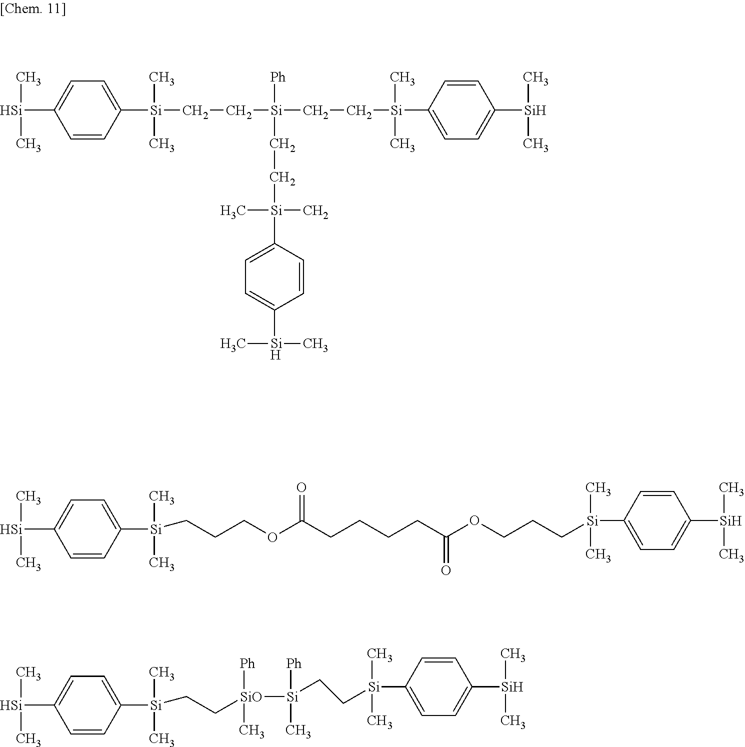

The organosilicon compound as component (C) may be used alone or in admixture of two or more.

Component (C) is blended in such amounts that a molar ratio of [total of SiH groups in component (C)]/[total of addition-reactive carbon-carbon double bonds in component (A)] may range from 0.2 to 5.0, preferably from 0.5 to 2.0.

Notably, the organosilicon compound as component (C) is free of a group selected from an addition-reactive carbon-carbon double bond-containing group, epoxy group, alkoxysilyl group, amide group, and carboxylic anhydride group. In this sense, component (C) is distinguished from component (G) having at least one such group, to be described later.

### [4] Component (D)

Component (D) is a catalyst for promoting hydrosilylation reaction of addition-reactive carbon-carbon double bonds attached to silicon atoms in the addition reaction product as component (A) with SiH groups in the organosilicon compound as component (C).

The catalyst used herein is not particularly limited as long as it promotes the hydrosilylation reaction. Suitable catalysts include, for example, platinum group metals such as platinum, palladium and rhodium, chloroplatinic acid, alcohol-modified chloroplatinic acids, coordination compounds of chloroplatinic acid with olefins, vinylsiloxanes, or acetylene compounds, and platinum group metal compounds such as tetrakis(triphenylphosphine)palladium and chlorotris(triphenylphosphine)rhodium, which may be used alone or in admixture.

Among these, preference is given to platinum compounds such as chloroplatinic acid, alcohol-modified chloroplatinic acids, and coordination compounds of chloroplatinic acid with olefins, vinylsiloxanes, or acetylene compounds. The platinum compounds may be used as being carried on supports such as inorganic oxides, resins and carbon.

The catalyst as component (D) may be used in an amount effective as the hydrosilylation catalyst and preferably in such an amount as to provide 0.1 to 1,000 ppm, more preferably 1 to 500 ppm by weight of platinum group metal based on the total weight of components (A) and (C).

### [5] Component (E)

Component (E) is hydrophobic fumed silica in the form of silica fine particles whose surfaces are hydrophobized by reaction of silanol groups on the particle surface with a surface modifying agent.

The hydrophobic fumed silica should preferably have a specific surface area of at least 50 m²/g, more preferably at least 80 m²/g, even more preferably at least 100 m²/g as measured by the BET method although it is not critical.

The hydrophobic fumed silica should preferably have a hydrophobicity value of at least 40%, more preferably at least 45% as measured by the methanol titration method although it is not critical.

In general, fumed silica is prepared by burning a mixture of H₂ and O₂ gases to create a flame at 1,100 to 1,400° C. and applying the flame to SiCl₄ gas for oxidation and hydrolysis. Primary particles of fumed silica are spherical ultrafine particles composed mainly of amorphous silicon dioxide (SiO₂) and having an average particle size of about 5 to about 50 nm. The primary particles agglomerate together to form secondary particles having a particle size of several hundreds of nanometers. Since fumed silica is in ultrafine particle form and prepared by quenching, its surface structure is chemically active.

The surface modifying agent for modifying such silica surfaces is selected from alkylsilanes, for example, dimethyldichlorosilane, hexamethyldisilazane, octylsilane, and dimethylsilicone oil, with dimethyldichlorosilane being preferred.

Examples of component (E) include Aerosil® R8200, R972, R972V, R972CF, R974, R202, R805, R812, R812S, RY200, RY200S, and RX200 from Nippon Aerosil Co., Ltd.: and Reolosil® DM-10, DM-20, DM-20S, DM-30, and DM-30S from Tokuyama Corp.

Component (E) is preferably blended in an amount of 0.5 to 10 parts by weight, more preferably 1 to 5 parts by weight per 100 parts by weight of component (A).

### [6] Component (F)

The IR-transmissive curable composition of the invention may contain (F) a reaction inhibitor as an optional component for preventing the composition from thickening or gelling prior to heat curing.

Examples of the reaction inhibitor include 3-methyl-1-butyn-3-ol, 3-methyl-1-pentyn-3-ol, 3,5-dimethyl-1-hexyn-3-ol, 1-ethynylcyclohexanol, ethynyl methyl decyl carbinol, 3-methyl-3-trimethylsiloxy-1-butyne, 3-methyl-3-trimethylsiloxy-1-pentyne, 3,5-dimethyl-3-trimethylsiloxy-1-hexyne, 1-ethynyl-1-trimethylsiloxycyclohexane, bis(2,2-dimethyl-3-butynoxy)dimethylsilane, 1,3,5,7-tetramethyl-1,3,5,7-tetravinylcyclotetrasiloxane, and 1,1,3,3-tetramethyl-1,3-divinyldisiloxane, which may be used alone or in admixture.

Among these, preference is given to 1-ethynylcyclohexanol, ethynyl methyl decyl carbinol, and 3-methyl-3-trimethylsiloxy-1-butyne.

Component (F) is preferably blended in an amount of 0.01 to 2.0 parts by weight, more preferably 0.01 to 0.1 part by weight per 100 parts by weight of component (A). The range ensures for the inhibitor to fully exert a reaction inhibiting effect.

### [7] Component (G)

The IR-transmissive curable composition may contain (G) an adhesive aid as an optional component for providing the composition with adhesion to substrates.

The adhesive aid is typically an organic compound having at least one functional group or a plurality of functional groups selected from among (meth)acryloyl, epoxy, alkoxysilyl, amide, and carboxylic anhydride groups. Examples of the organic compound are shown below.

It is noted that component (G) is distinguished from component (C) in that component (G) has the aforementioned functional group.

As the adhesive aid, there may be used compounds based on organosiloxane skeleton, for example, vinyltrimethoxysilane (tradename KBM-1003 by Shin-Etsu Chemical Co., Ltd.), γ-(glycidyloxypropyl)trimethoxysilane (tradename KBM-403 by Shin-Etsu Chemical Co., Ltd.), and γ-(methacryloxypropyl)trimethoxysilane (tradename KBM-503 by Shin-Etsu Chemical Co., Ltd.).

Also, siloxane compounds having the following structural formulae are advantageously used as the adhesive aid.

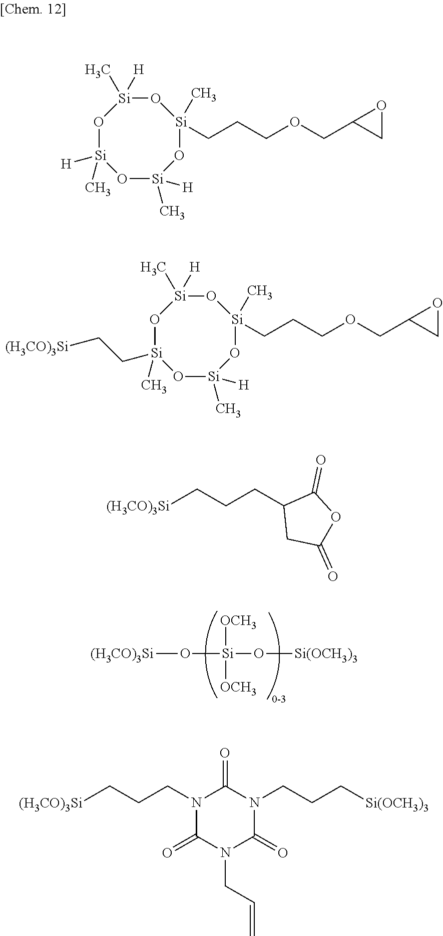

Further, adhesive aids free of organosiloxane skeleton may be used, for example, allyl glycidyl ether, vinyl cyclohexene monoxide, diethyl 2-allylmalonate, allyl benzoate, diallyl phthalate, tetraallyl pyromellitate (tradename TRIAM805 by Fujifilm Wako Pure Chemical Corp.), and triallyl isocyanurate.

The adhesive aid as component (G) may be used alone or in admixture.

Component (G) is blended in an amount of 0.05 to 10 parts by weight, more preferably 0.05 to 5 parts by weight per 100 parts by weight of component (A).

It is noted that the IR-transmissive curable composition may contain components other than components (A) to (E) and optional components (F) and (G) insofar as they do not compromise the object of the invention.

Exemplary other components include antioxidants, flame retardants, and pigments.

The IR-transmissive curable composition of the invention may be prepared by mixing all the components at a time, while it may be formulated as a two-pack type composition because reaction starts at room temperature when components (A), (C), and (D) coexist. The two-pack type composition may be, for example, a composition consisting of pack (i) containing components (A), (B), (D), and (E) and pack (ii) containing components (A), (C), and optional components.

In pack (i) containing component (E), the agglomeration of component (B) with time is controlled.

With respect to the method and conditions for curing the IR-transmissive curable composition, any well-known methods and conditions may be employed. For example, the composition may be cured under conditions: 100 to 180° C. and 10 minutes to 5 hours.

A cured product of the IR-transmissive curable composition should preferably have an average light transmittance of up to 40% over wavelength 350 to 650 nm and an average light transmittance of at least 60% over wavelength 800 to 900 nm, more preferably an average light transmittance of up to 20% over wavelength 350 to 650 nm and an average light transmittance of at least 70% over wavelength 800 to 900 nm.

### EXAMPLES

Synthesis Examples, Examples and Comparative Examples are shown below for further illustrating the invention although the invention is not limited thereto.

### [1] Synthesis of Addition Reaction Product as Component (A)

### Synthesis Example 1

A 5-L four-necked flask equipped with a stirrer, condenser, dropping funnel and thermometer was charged with 1,785 g (14.88 mol) of vinylnorbornene (tradename V0062 by Tokyo Chemical Co., Ltd.; approximately equimolar isomer mixture of 5-vinylbicyclo[2.2.1]hept-2-ene and 6-vinylbicyclo[2.2.1]hept-2-ene) and 455 g of toluene, and heated at 85° C. in an oil bath.

To the flask, 3.6 g of 5 wt % platinum metal-carrying carbon powder was added. With stirring, 1,698 g (8.75 mol) of 1,4-bis(dimethylsilyl)benzene was added dropwise over 180 minutes. At the end of dropwise addition, stirring was continued at 110ºC for 24 hours, after which the flask was cooled at 25° C. Thereafter, the platinum metal-carrying carbon was filtered off, and the toluene and excess vinylnorbomnene were distilled off under reduced pressure, yielding 3,362 g of a reaction product (A-1) in colorless transparent oil form (viscosity 12,820 mPa·s at 25° ° C.).

On analysis by FT-IR, NMR, and GPC, the reaction product was a mixture consisting of about 41 mol % of the compound with n=0, about 32 mol % of the compound with n=1, and about 27 mol % of the compound with n=2, as represented by the following formula. Also, the mixture contained 0.36 mol/100 g of addition-reactive carbon-carbon double bonds.

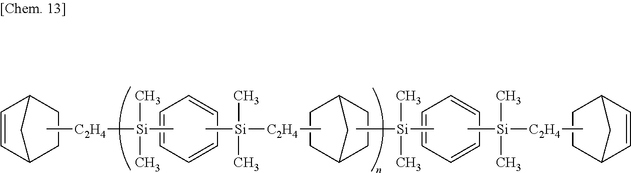

### [2] Preparation of IR-Transmissive Curable Composition

### Examples 1, 2 and Comparative Examples 1, 2

Compositions 1-i (pack i), 1-ii (pack ii), 2-i (pack i), 2-ii (pack ii), 3-i (pack i), 3-ii (pack ii), 4-i (pack i), and 4-ii (pack ii) were prepared by mixing components (A) to (G) in the amounts (parts by weight) shown in Table 1.

An IR-transmissive curable composition of Example 1 was prepared by mixing compositions 1-i and 1-ii in a weight ratio of 1:1.

An IR-transmissive curable composition of Example 2 was prepared by mixing compositions 2-i and 2-ii in a weight ratio of 1:1.

An IR-transmissive curable composition of Comparative Example 1 was prepared by mixing compositions 3-i and 3-ii in a weight ratio of 1:1.

An IR-transmissive curable composition of Comparative Example 2 was prepared by mixing compositions 4-i and 4-ii in a weight ratio of 1:1.

### Component (A)

(A-1) The addition reaction product (mixture) obtained in Synthesis Example 1

### Component (B)

(B-1) Plast Black 8995 (Arimoto Chemical Co., Ltd.)
(B-2) SDO-3 (Arimoto Chemical Co., Ltd.)

### Component (C)

(C-1) Organohydrogenpolysiloxane having the following formula (9)

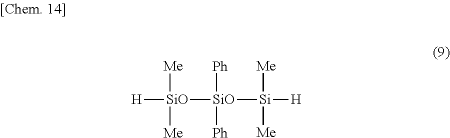

(C-2) Organohydrogenpolysiloxane having the following formula (10)

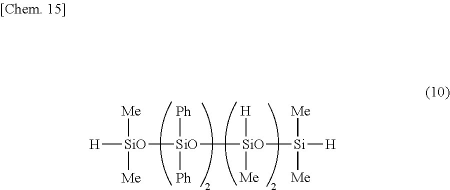

The arrangement of siloxane units within the parentheses is random, alternate or blockwise.

### Component (D)

(D-1) A dilution of platinum hexachloride 1,3-divinyltetramethyldisiloxane with linear dimethylpolysiloxane having the following formula (11) (platinum content 1 wt %, viscosity 600 mPa·s)

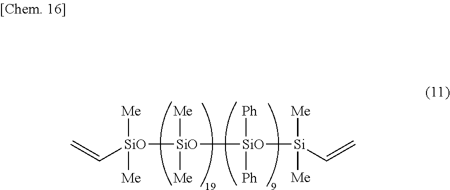

The arrangement of siloxane units within the parentheses is random, alternate or blockwise.

### Component (E)

(E-1) Reolosil DM-30S (hydrophobic fumed silica surface-treated with dimethyldichlorosilane, hydrophobicity value 52% as measured by the methanol titration method, average primary particle size 7 nm, specific surface area 210-260 m²/g, by Tokuyama Corp.)
(E-2) Aerosil 380 (hydrophilic fumed silica, average primary particle size 7 nm, by Nippon Aerosil Co., Ltd.)

### Component (F)

(F-1) ethynyl methyl decyl carbinol
(F-2) Compound having the following formula (12)

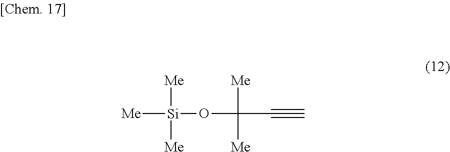

### Component (G)

(G-1) Compound having the following formula (13)

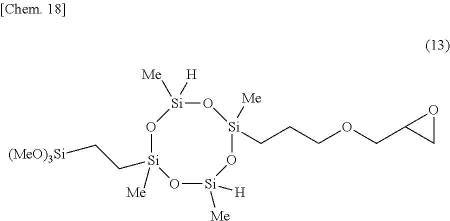

### [Storage Test]

Each of compositions 1-i, 2-i, 3-i and 4-i was stored at 23° ° C. for 1 week, after which it was visually observed for agglomeration of the dye. It was rated good (◯) for no agglomerates and poor (x) for agglomerates, with the results shown in Table 1.

Since reaction takes place in each composition from the point of time when packs i and ii are mixed together, pack i was evaluated for storage stability in the two-pack divided storage state prior to mixing.

TABLE 1

| | | | | | | Comparative | | Comparative | |
|---|---|---|---|---|---|---|---|---|---|
| | | Example 1 | | Example 2 | | Example 1 | | Example 2 | |
| | | 1-i | 1-ii | 2-i | 2-ii | 3-i | 3-ii | 4-i | 4-ii |
| Component (A) | A-1 | 87.8 | 12.1 | 88.6 | 11.4 | 88.8 | 11.2 | 87.9 | 12.1 |
| Component (B) | B-1 | 3 | — | 1.5 | — | 3 | — | 3 | — |
| | B-2 | — | — | 0.75 | — | — | — | — | — |
| Component (C) | C-1 | — | 18.6 | — | 18.6 | — | 18.6 | 18.6 | 18.6 |
| | C-2 | — | 53.1 | — | 53.1 | — | 53.1 | 53.1 | 53.1 |
| Component (D) | D-1 | 0.2 | — | 0.2 | — | 0.2 | 0.2 | 0.2 | — |
| Component (E) | E-1 | 1.8 | — | 1.8 | — | — | — | — | — |
| | E-2 | — | — | — | — | — | — | 1.8 | — |
| Component (F) | F-1 | — | 0.17 | — | 0.17 | — | 0.17 | — | 0.17 |
| | F-2 | — | 1.02 | — | 1.02 | — | 1.02 | — | 1.02 |
| Component (G) | G-1 | — | 8 | — | 8 | — | 8 | — | 8 |

| H/Vi* | 1.3 | | 1.3 | | 1.3 | | 1.3 | |
|---|---|---|---|---|---|---|---|---|
| Storage test | ∘ | — | ∘ | — | x | — | x | — |

*[total number of SiH groups in component (C)]/[total number of addition-reactive carbon-carbon double bonds in component (A)]

### [Light Transmittance]

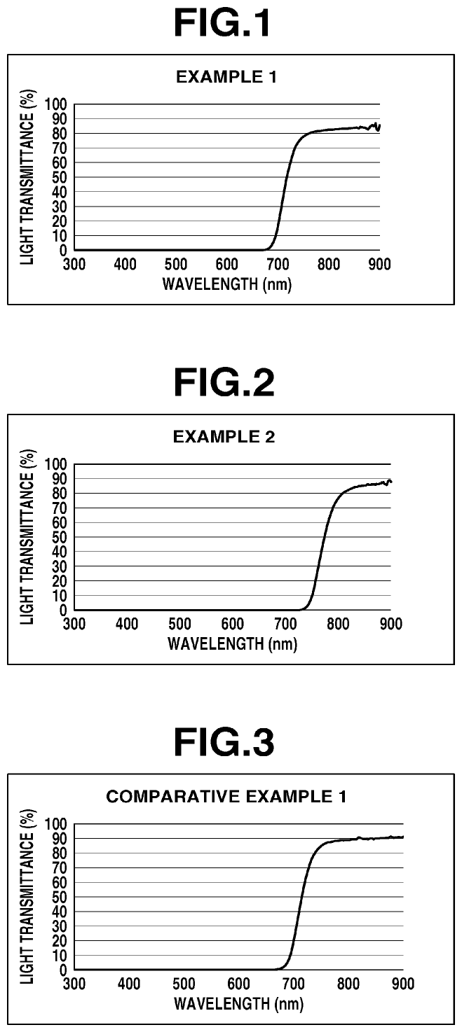

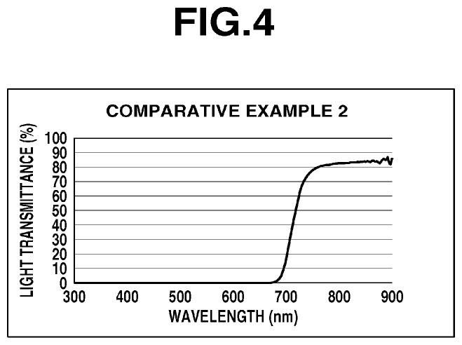

Each of the IR-transmissive curable compositions prepared in Examples and Comparative Examples was cast into a mold and cured under conditions: 150° C.×4 hour into a cured product having a thickness of 0.4 mm. The cured product was measured for linear light transmittance by a spectrophotometer Model U-3310 (Hitachi, Ltd.), from which an average light transmittance over wavelength 350 to 650 nm and an average light transmittance over wavelength 800 to 900 nm were determined. The results are shown in Table 2. FIGS. 1 to 4 show the UV/Vis transmission spectra of the cured products.

TABLE 2

| | | | | Compar- | Compar- |
|---|---|---|---|---|---|
| | | | | ative | ative |
| | | Exam- | Exam- | Exam- | Exam- |
| | | ple 1 | ple 2 | ple 1 | ple 2 |
| Average | 350-650 nm | 0 | 0 | 0 | 0 |
| transmittance | 800-900 nm | 85 | 85 | 89 | 83 |
| (%) | | | | | |

As seen from Tables 1 and 2, the IR-transmissive curable compositions (specifically, pack i) in Examples 1 and 2 contain hydrophobic fumed silica which is effective for preventing the dye from agglomeration and thus have improved storage stability. The compositions cure into products having high IR transmittance and satisfactory visible light blockage.

By contrast, pack i in Comparative Example 1 not containing hydrophobic fumed silica and pack i in Comparative Example 2 containing hydrophilic fumed silica show agglomeration of the dye after storage at 23° C. for 1 week.

1. An infrared-transmissive curable composition comprising components (A) to (E):
(A) an addition reaction product between (a) a compound having two silicon-bonded hydrogen atoms per molecule, represented by the formula (1) and (b) a polycyclic hydrocarbon having two addition-reactive carbon-carbon double bonds per molecule, the addition reaction product having two addition-reactive carbon-carbon double bonds per molecule, 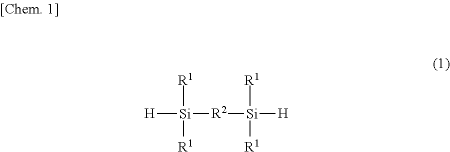
wherein R¹ is each independently a C₁-C₁₂ monovalent hydrocarbon group or C₁-C₆ alkoxy group, which may be substituted with halogen, cyano or glycidoxy, and R² is a C₁-C₁₂ substituted or unsubstituted divalent hydrocarbon group,
(B) a dye having an absorption band in the wavelength region of 350 to 650 nm and capable of transmitting at least a portion of light of wavelength 800 to 900 nm,
(C) an organosilicon compound having at least two silicon-bonded hydrogen atoms per molecule, and free of a group selected from an addition-reactive carbon-carbon double bond-containing group, epoxy group, alkoxysilyl group, amide group, and carboxylic anhydride group,
(D) a hydrosilylation reaction catalyst, and
(E) hydrophobic fumed silica.

2. The infrared-transmissive curable composition of claim 1 wherein the polycyclic hydrocarbon is at least one of 5-vinylbicyclo[2.2.1]hept-2-ene and 6-vinylbicyclo[2.2.1]hept-2-ene.

3. The infrared-transmissive curable composition of claim 1 or 2 wherein component (A) has the formula (2): 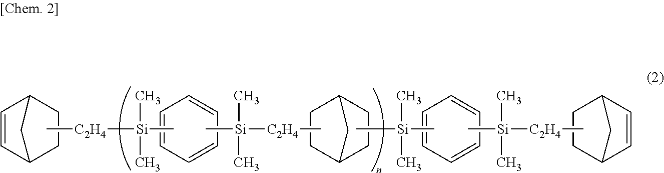
wherein n is an integer of 0 to 50.

4. A cured product of the infrared-transmissive curable composition of any one of claims 1 to 3, having an average light transmittance of up to 40% over wavelength 350 to 650 nm and an average light transmittance of at least 60% over wavelength 800 to 900 10 nm at both a thickness of 2 mm and 0.4 mm.

5. An opto-semiconductor package comprising an opto-semiconductor device encapsulated with a cured product of the infrared-transmissive curable composition of any one of claims 1 to 3.
